(19) United States
(12) Patent Application Publication
(10) Pub. No.: US 2019/0386059 A1
(43) Pub. Date: Dec. 19, 2019

(54) DISPLAY WITH CONCENTRATED LIGHT EMITTING DEVICES

(71) Applicant: MIKRO MESA TECHNOLOGY CO., LTD., APIA (WS)

(72) Inventor: Li-Yi CHEN, Tainan City (TW)

(21) Appl. No.: 16/008,005

(22) Filed: Jun. 13, 2018

(51) Int. Cl. H01L 27/15

(52) U.S. Cl. CPC H01L 27/156

(57) ABSTRACT

A display is provided. The display includes a substrate and a plurality of light emitting devices. The substrate has at least one pixel defined thereon. A plurality of sub-pixels are defined in said pixel. The light emitting devices are respectively located within said sub-pixels. A distance between a geometrical center of one of said sub-pixels and a common geometrical center of said light emitting devices is greater than a distance between a geometrical center of the light emitting device in said one of said sub-pixels and the common geometrical center of said light emitting devices. A relative position of the light emitting device with respect to its corresponding sub-pixel is different from at least one of relative positions of a remaining part of said light emitting devices with respect to their respectively corresponding sub-pixels.

### BACKGROUND

### Field of Invention

The present disclosure relates to a display with a concentrated arrangement of light emitting devices within a pixel.

Description of Related Art

The statements in this section merely provide background information related to the present disclosure and do not necessarily constitute prior art.

In recent years, micro devices such as micro light emitting devices, or specifically, light emitting diodes (LEDs) have become popular in general and commercial lighting applications. As light sources, LEDs have many advantages including low energy consumption, long lifetime, small size, and fast switching, and hence conventional lighting, such as incandescent lighting, is gradually replaced by LED lights. These properties are promising for applications on displays.

As a size of a light emitting device is gradually reduced, many new issues related to luminous quality emerge.

### SUMMARY

According to some embodiments of the present disclosure, a display is provided. The display includes a substrate and a plurality of light emitting devices. The substrate has at least one pixel defined thereon. A plurality of sub-pixels are defined in said pixel. The light emitting devices are respectively located within said sub-pixels. A distance between a geometrical center of one of said sub-pixels and a common geometrical center of said light emitting devices is greater than a distance between a geometrical center of the light emitting device in said one of said sub-pixels and the common geometrical center of said light emitting devices. A relative position of the light emitting device with respect to its corresponding sub-pixel is different from at least one of relative positions of a remaining part of said light emitting devices with respect to their respectively corresponding sub-pixels.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a schematic top view of a portion of a display with some pixels having sub-pixels defined thereon and some light emitting devices respectively located within the sub-pixels according to some embodiments of the present disclosure;

FIG. 1B is a schematic top view of a portion of a display with some pixels having sub-pixels defined thereon and some light emitting devices respectively located within the sub-pixels according to some embodiments of the present disclosure;

FIG. 1C is a schematic top view of a portion of a display with some pixels having sub-pixels defined thereon and some light emitting devices respectively located within the sub-pixels according to some embodiments of the present disclosure;

FIG. 2A is a schematic top view of a portion of a display with some pixel having sub-pixels defined thereon and some light emitting devices respectively located within the sub-pixels according to some embodiments of the present disclosure;

FIG. 2B is a schematic top view of a portion of a display with some pixels having sub-pixels defined thereon and some light emitting devices respectively located within the sub-pixels according to some embodiments of the present disclosure;

FIG. 2C is a schematic top view of a portion of a display with some pixels having sub-pixels defined thereon and some light emitting devices respectively located within the sub-pixels according to some embodiments of the present disclosure;

FIG. 3A is a schematic top view of a portion of a display with some pixels having sub-pixels defined thereon and some light emitting devices respectively located within the sub-pixels according to some embodiments of the present disclosure;

FIG. 3B is a schematic top view of a portion of a display with some pixels having sub-pixels defined thereon and some light emitting devices respectively located within the sub-pixels according to some embodiments of the present disclosure;

FIG. 3C is a schematic top view of a portion of a display with some pixels having sub-pixels defined thereon and some light emitting devices respectively located within the sub-pixels according to some embodiments of the present disclosure;

FIG. 4 is a schematic top view of a portion of a display with a pixel having sub-pixels defined thereon and some light emitting devices respectively located within the sub-pixels according to some embodiments of the present disclosure;

FIG. 5 is a schematic top view of a portion of a display with a pixel having sub-pixels with different shapes defined thereon and some light emitting devices respectively located within the sub-pixels according to some embodiments of the present disclosure;

FIG. 6 is a schematic top view of a portion of a display with a pixel having sub-pixels defined thereon and some light emitting devices respectively located within the sub-pixels according to some embodiments of the present disclosure;

FIG. 7 is a schematic top view of a portion of a display with a pixel defined thereon and some light emitting devices located within said pixel according to some embodiments of the present disclosure; and

FIG. 8 is a schematic top view of a sub-pixel with a light emitting device located therein according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the present disclosure. In other instances, well-known semiconductor processes and manufacturing techniques have not been described in particular detail in order to not unnecessarily obscure the present disclosure. Reference throughout this specification to “one embodiment,” “an embodiment”, “some embodiments” or the like means that a particular feature, structure, configuration, or characteristic described in connection with the embodiment is included in at least one embodiment of the disclosure. Thus, the appearances of the phrase “in one embodiment,” “in an embodiment”, “in some embodiments” or the like in various places throughout this specification are not necessarily referring to the same embodiment of the disclosure. Furthermore, the particular features, structures, configurations, or characteristics may be combined in any suitable manner in one or more embodiments.

The terms “over,” “to,” “between” and “on” as used herein may refer to a relative position of one layer with respect to other layers. One element “over” or “on” another element or bonded “to” another element may be directly in contact with the other element or may have one or more intervening element. One element “between” elements may be directly in contact with the elements or may have one or more intervening elements.

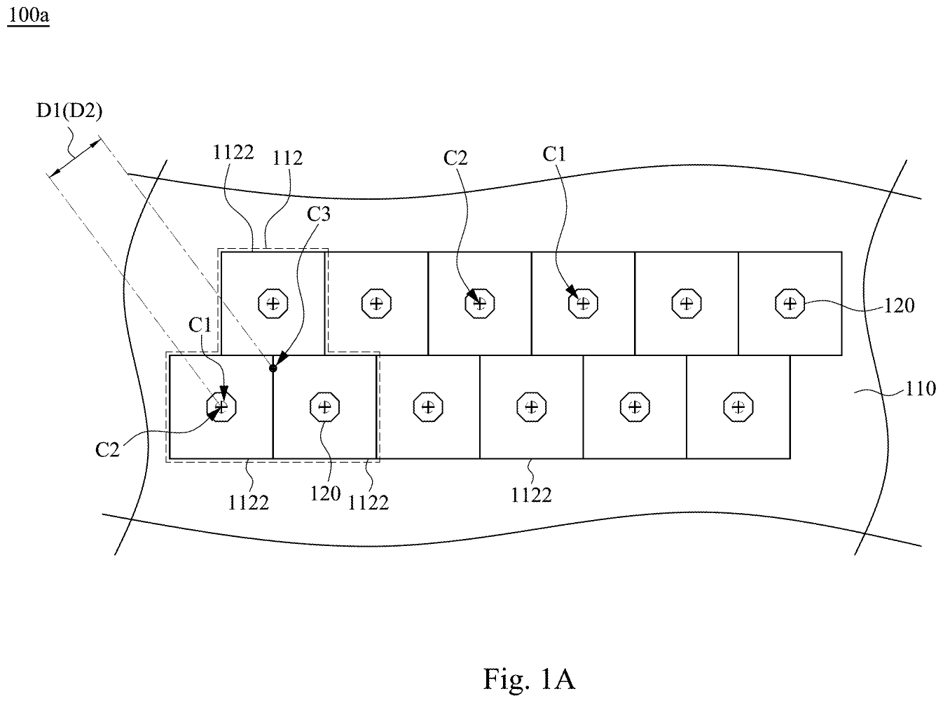

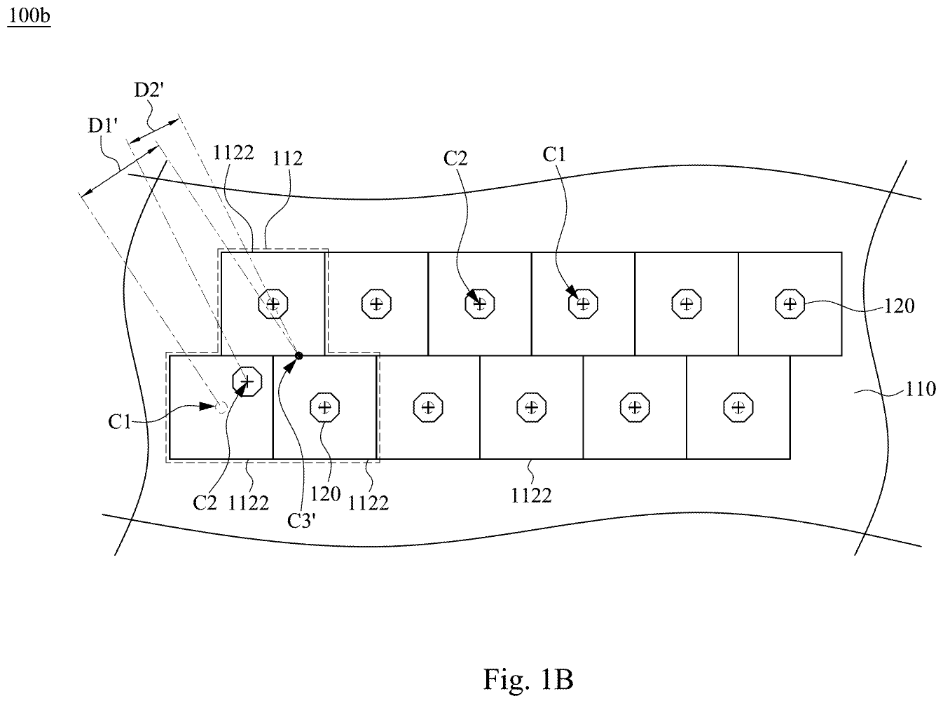

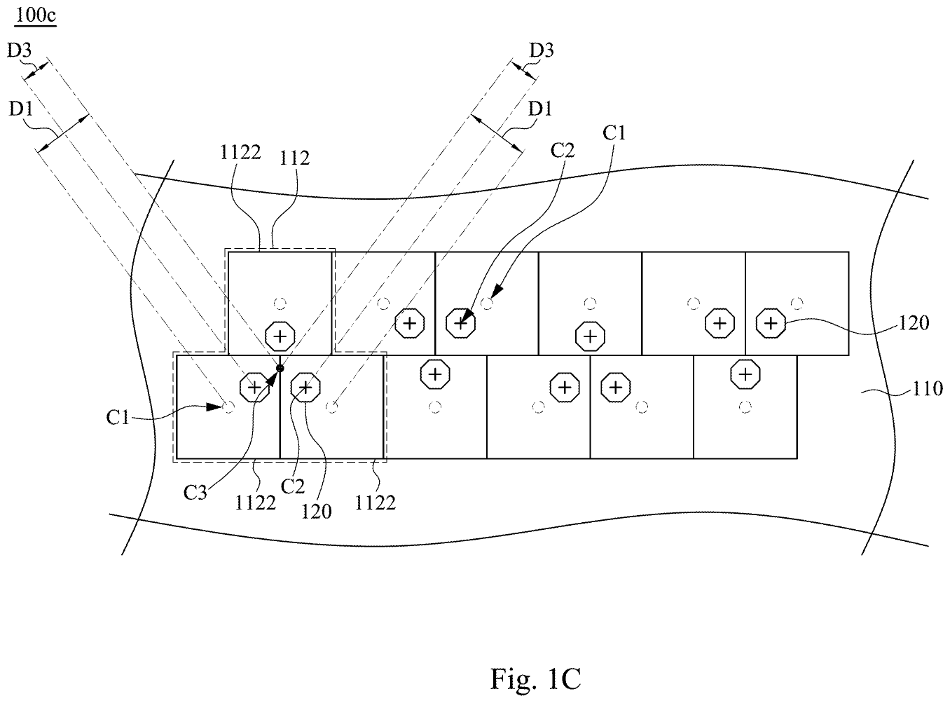

Reference is made to FIG. 1A. FIG. 1A is a schematic top view of a portion of a display 100a with some pixels 112 having sub-pixels 1122 defined thereon and some light emitting devices 120 respectively located within the sub-pixels 1122 according to some embodiments of the present disclosure. The top view here refers to seeing along a direction from a dominant light exit surface to the display 100a. Said definition of the top view can be applied to the entire disclosure. In some embodiments, the display 100a includes a substrate 110 and a plurality of light emitting devices 120. The substrate 110 has at least one pixel 112 defined thereon, and a plurality of sub-pixels 1122 are defined in said pixel 112. The light emitting devices 120 are respectively located within said sub-pixels 1122. In some embodiments, geometrical centers respectively of three of the sub-pixels 1122 are arranged in a triangular arrangement as shown in FIG. 1A and also in FIGS. 1B and 1C as will be described later. In the embodiments illustrated by FIG. 1A, there are a plurality of pixels 112 (only one of them is indicated by a dotted frame in FIG. 1A for clarity and simplicity), each of the pixels 112 has three sub-pixels 1122 defined thereon, and each of the sub-pixels 1122 has a light emitting device 120 located therein. Geometrical centers C1 of the sub-pixels 1122 are indicated by dotted circles in FIG. 1A. Geometrical centers C2 of some light emitting devices 120 are indicated by crosses in FIG. 1A. The geometrical centers C1 of the sub-pixels 1122 are overlapped with the geometrical centers C2 respectively of each of the light emitting devices 120 as shown in FIG. 1A in a direction normal to an extension direction of the substrate 110. Geometrical centers C1 and C2 are selectively indicated in different sub-pixels 1122 and light emitting devices 120. A common geometrical center C3 of the light emitting devices 120 located within said one of the pixels 112 is also indicated in FIG. 1A. As such, under a condition within the same pixel 112, a distance D1 between the geometrical center C1 of one of the sub-pixels 1122 and the common geometrical center C3 of the light emitting devices 120 is the same as a distance D2 between the geometrical center C2 of the light emitting device 120 in said one of the sub-pixels 1122 and the common geometrical center C3 as shown in FIG. 1A. To put it briefly, a distance between the geometrical center C1 and the common geometrical center C3 in one of the pixels 112 is the distance D1, a distance between the geometrical center C2 and the common geometrical center C3 in said one of the pixels 112 is the distance D2, and the distance D1 is equal to the distance D2 in the embodiments as illustrated by FIG. 1A.

The above embodiments illustrated by FIG. 1A can be a basis for the following descriptions of various embodiments which mostly, can be regarded as modified embodiments from FIG. 1A, and thus coming up illustrations will be written in more simplified way.

Reference is made to FIGS. 1A and 1B. FIG. 1B is a schematic top view of a portion of a display 100b with some pixels 112 having sub-pixels 1122 defined thereon and some light emitting devices 120 respectively located within the sub-pixels 1122 according to some embodiments of the present disclosure. The main difference between the embodiments illustrated by FIG. 1B and the embodiments illustrated by FIG. 1A is that, one of the light emitting devices 120 in the indicated pixel 112 is dislocated by a distance towards the common geometrical center C3 shown in FIG. 1A (i.e., the original common geometrical center C3 which is without dislocation). After the dislocation, a distance D2′ is the distance between the geometrical center C2 of said one of the light emitting devices 120 with said dislocation and a dislocated common geometrical center C3′ as shown in FIG. 1B. Therefore, a distance D1′ (which also becomes greater in length as compared with the distance D1 shown in FIG. 1A) is greater than the distance D2′ for one of the sub-pixels 1122 in the pixel 112 of the embodiments as illustrated by FIG. 1B, and thus under a condition within the same pixel 112, a relative position of one of the light emitting devices 120 with respect to its corresponding sub-pixel 1122 is different from relative positions of a remaining two light emitting devices 120 with respect to their respectively corresponding sub-pixels 1122. As such, the pixel 112 as shown in FIG. 1B can have a better light mixing effect of the light emitting devices 120 within said pixel 112 due to a more concentrated arrangement compared with that of FIG. 1A. It should be noted that, although FIG. 1B only demonstrates a dislocation of one light emitting device 120 in one indicated pixel 112, other light emitting devices 120 in pixels other than the indicated pixel 112 (which are also pixels 112 but without indication for clarity and simplicity of the figure) can also have dislocations and shall not be limited by FIG. 1B.

Reference is made to FIG. 1C. FIG. 1C is a schematic top view of a portion of a display 100c with some pixels 112 having sub-pixels 1122 defined thereon and some light emitting devices 120 respectively located within the sub-pixels 1122 according to some embodiments of the present disclosure. The main difference between the embodiments illustrated by FIG. 1C and the embodiments illustrated by FIG. 1A is that, all of the light emitting devices 120 within one of the pixels 112 are dislocated by a distance (D1-D3) toward the common geometrical center C3 as compared with the embodiments as illustrated by FIG. 1A. The distance D3 is the distance between the geometrical center C2 of the light emitting device 120 in one of the sub-pixels 1122 and the common geometrical center C3 as shown in FIG. 1C. Therefore, the distance D1 is greater than the distance D3 for the sub-pixels 1122 in the pixel 112 of the embodiments as illustrated by FIG. 1C, and thus under a condition within the same pixel 112, relative positions of the light emitting devices 120 with respect to their corresponding sub-pixel 1122 respectively are different from one another. As such, the pixel 112 as shown in FIG. 1C can have a better light mixing effect of the light emitting devices 120 within said pixel 112 due to a more concentrated arrangement compared with that of FIG. 1A. It should be noted that, although FIG. 1C only demonstrates the same distance of dislocations of all light emitting devices 120, different distances of dislocations can be adopted for different light emitting devices 120 according to practical applications and shall not be limited by FIG. 1C.

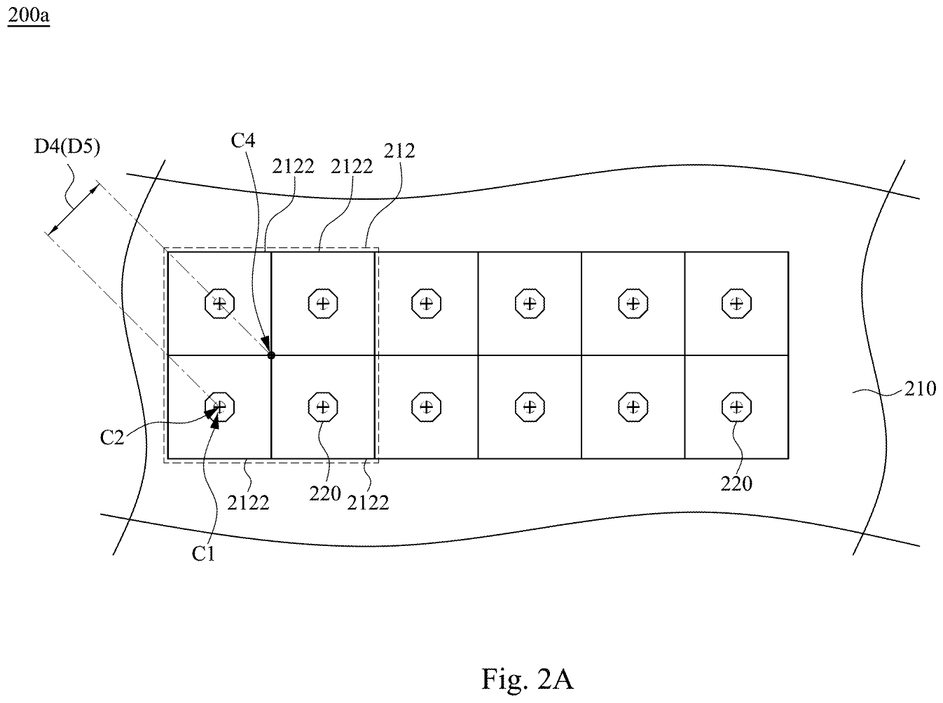

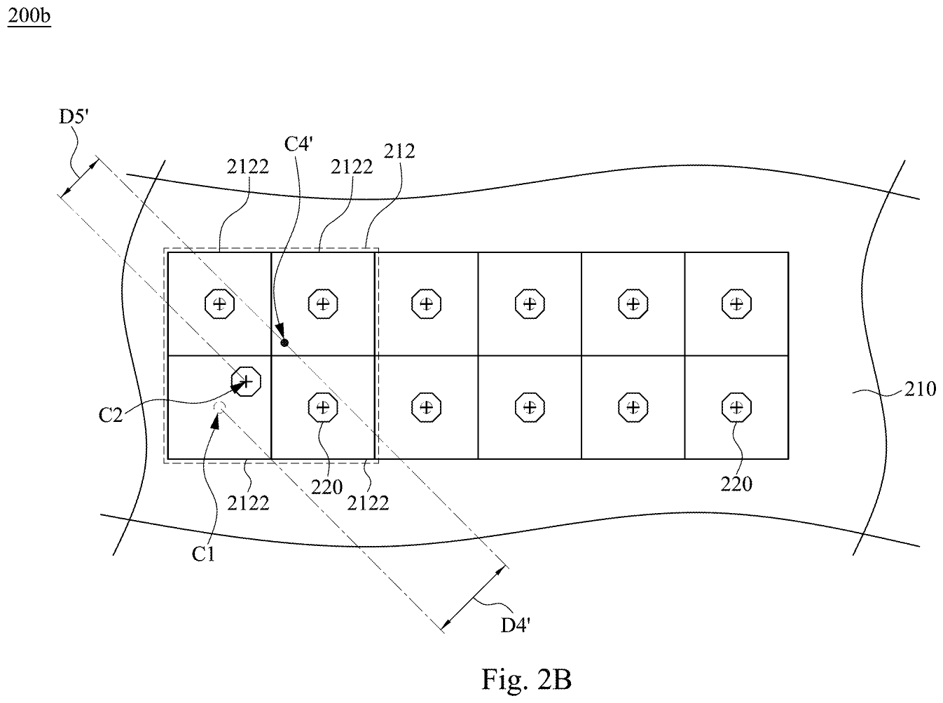

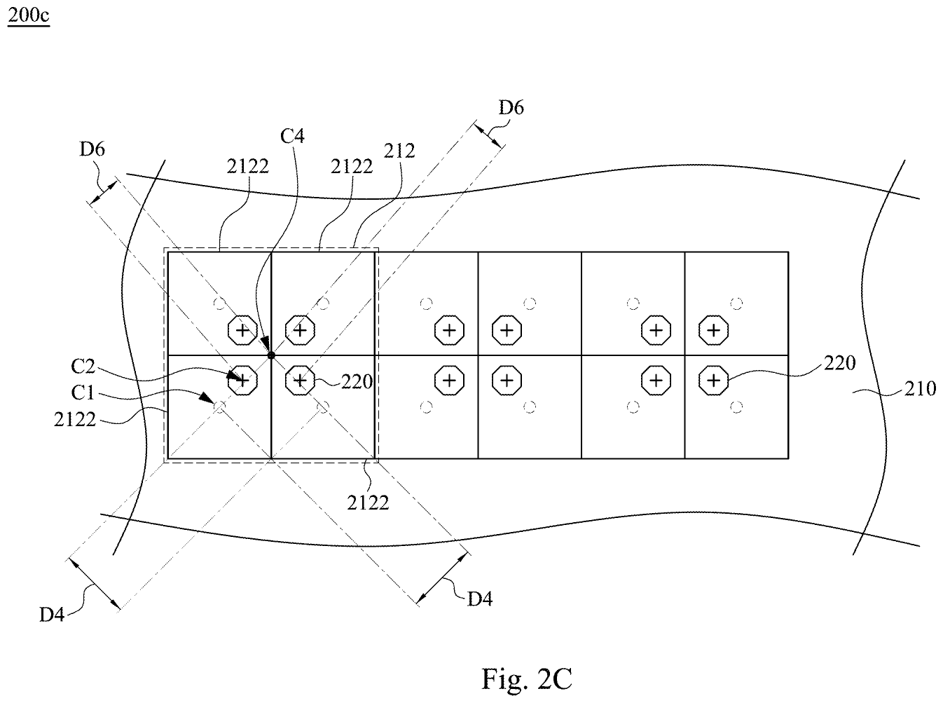

One pixel 112 can have a different number of sub-pixels 1122 in different embodiments or, in different displays. FIGS. 1A to 1C each shows three sub-pixels 1122 within one pixel 112. In the following, FIGS. 2A to 2C each shows four sub-pixels 1122 within one pixel 112. Reference is made to FIG. 2A. FIG. 2A is a schematic top view of a portion of a display 200a with a pixel 212 having sub-pixels 2122 defined thereon and some light emitting devices 220 respectively located within the sub-pixels 2122 according to some embodiments of the present disclosure. Similar to the embodiments illustrated by FIG. 1A, the embodiments illustrated by FIG. 2A can also be regarded as a basic configuration compared with modified embodiments which will be shown later in FIGS. 2B and 2C. The main difference between the embodiments illustrated by FIG. 2A and the embodiments illustrated by FIG. 1A is that, there are four sub-pixels 2122 in each of the pixels 212 which have light emitting devices 220 located respectively therein in FIG. 2A. In some embodiments, geometrical centers C1 respectively of said four sub-pixels are arranged in a quadrilateral arrangement as shown in FIG. 2A and also in FIGS. 2B and 2C as will be described later. Similar structural features between FIGS. 2A and 1A are not repeated herein. The embodiments illustrated by FIG. 2A also has the geometrical centers C1 of the sub-pixels 2122 that are overlapped in a direction normal to an extension direction of the substrate 210 with the geometrical centers C2 of the light emitting devices 220 respectively in one of the pixels 212. A distance between the geometrical center C1 and the common geometrical center C4 of the light emitting devices 120 located within one pixel 212 is the distance D4, a distance between the geometrical center C2 and the common geometrical center C4 is the distance D5, and the distance D4 is equal to the distance D5 in the embodiments as illustrated by FIG. 2A.

Reference is made to FIGS. 2A and 2B. FIG. 2B is a schematic top view of a portion of a display 200b with a pixel 212 having sub-pixels 2122 defined thereon and some light emitting devices 220 respectively located within the sub-pixels 2122 according to some embodiments of the present disclosure. The main difference between the embodiments illustrated by FIG. 2B and the embodiments illustrated by FIG. 2A is that, one of the light emitting devices 220 in the indicated pixel 212 is dislocated by a distance towards the common geometrical center C4 shown in FIG. 2A (i.e., the original common geometrical center C4 which is without dislocation). After the dislocation, a distance D5′ is the distance between the geometrical center C2 of said one of the light emitting devices 220 with said dislocation and a dislocated common geometrical center C4′ as shown in FIG. 2B. Therefore, a distance D4′ (which also becomes greater in length as compared with the distance D4 shown in FIG. 2A) is greater than the distance D5′ for one of the sub-pixels 2122 in the pixel 212 of the embodiments as illustrated by FIG. 2B, and thus under a condition within the same pixel 212, a relative position of one of the light emitting devices 220 with respect to its corresponding sub-pixel 2122 is different from relative positions of a remaining three of the light emitting devices 220 with respect to their respectively corresponding sub-pixels 2122. As such, the pixel 212 as shown in FIG. 2B can have a better light mixing effect of the light emitting devices 220 within said pixel 212 due to a more concentrated arrangement compared with that of FIG. 2A. It should be noted that, although FIG. 2B only demonstrates a dislocation of one light emitting device 220 in one indicated pixel 212, other light emitting devices 220 in pixels other than the indicated pixel 212 (which are also pixels 212 but without indication for clarity and simplicity of the figure) can also have dislocations and shall not be limited by FIG. 2B.

Reference is made to FIG. 2C. FIG. 2C is a schematic top view of a portion of a display 200c with some pixels 212 having sub-pixels 2122 defined thereon and some light emitting devices 220 respectively located within the sub-pixels 2122 according to some embodiments of the present disclosure. The main difference between the embodiments illustrated by FIG. 2C and the embodiments illustrated by FIG. 2A is that, all of the light emitting devices 220 within one of the pixels 212 are dislocated by a distance (D4-D6) towards the common geometrical center C4 as compared with the embodiments as illustrated by FIG. 2A. The distance D6 is the distance between the geometrical center C2 of the light emitting device 220 in one of the sub-pixels 2122 and the common geometrical center C4 as shown in FIG. 2C. Therefore, the distance D4 is greater than the distance D6 for the sub-pixels 2122 in the pixel 212 of the embodiments as illustrated by FIG. 2C, and under a condition within the same pixel 212, relative positions of the light emitting devices 220 with respect to their corresponding sub-pixel 2122 respectively are different from one another. As such, the pixel 212 as shown in FIG. 2C can have a better light mixing effect of the light emitting devices 220 within said pixel 212 due to a more concentrated arrangement compared with that of FIG. 2A. It should be noted that, although FIG. 2C only demonstrates the same distance of dislocations of all light emitting devices 220, different distances of dislocations can be adopted for different light emitting devices 220 according to practical applications and shall not be limited by FIG. 2C.

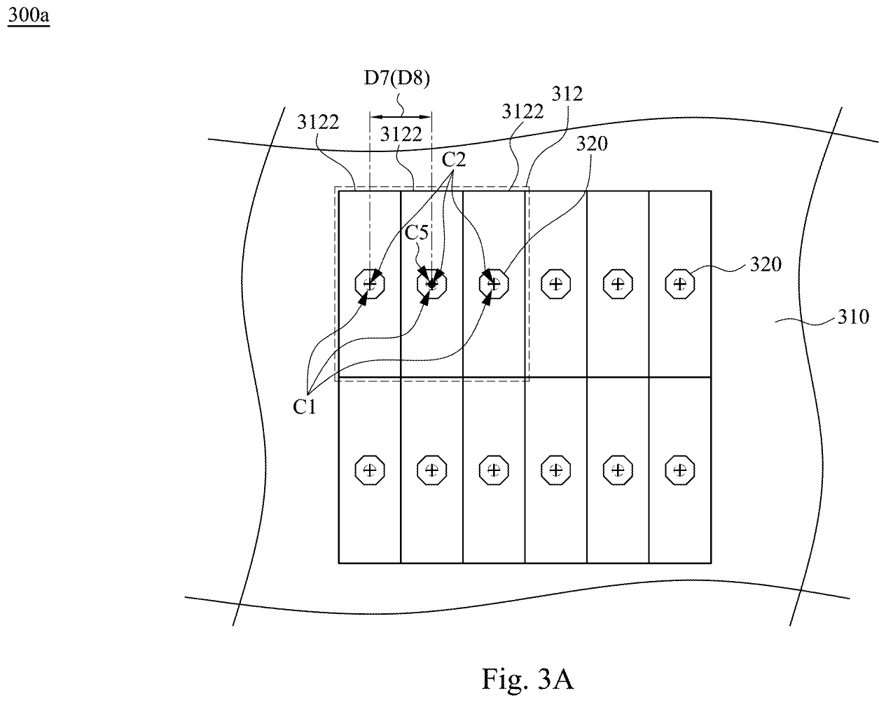

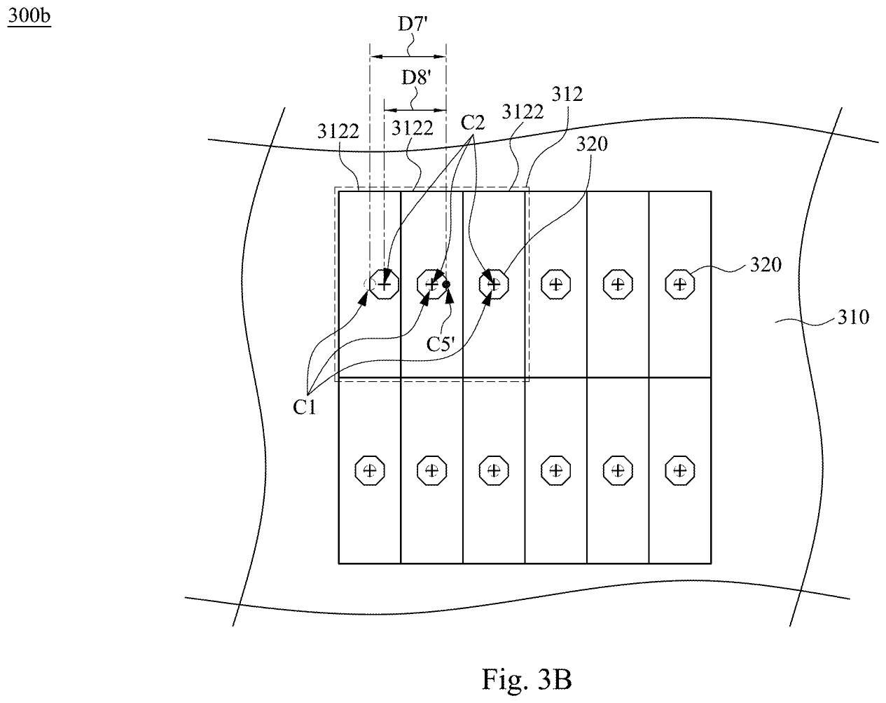

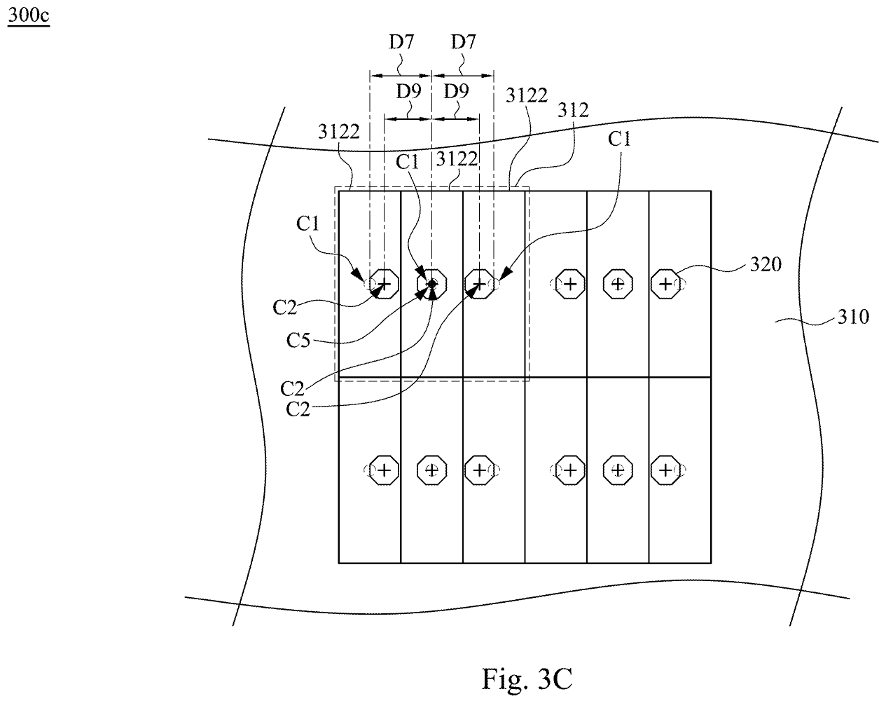

An arrangement of sub-pixels in one pixel can be different according to practical applications. FIGS. 1A to 1C each shows geometrical centers C1 respectively of three sub-pixels 1122 arranged in a triangular shape within one pixel 112. In some other embodiments, geometrical centers respectively of three sub-pixels in a pixel are arranged in a stripe arrangement. For example, FIGS. 3A to 3C each shows geometrical centers C1 respectively of three sub-pixels 3122 arranged in a stripe arrangement within one pixel 312. Reference is made to FIGS. 3A. FIG. 3A is a schematic top view of a portion of a display 300a with some pixels 312 having sub-pixels 3122 defined thereon and some light emitting devices 320 respectively located within the sub-pixels 3122 according to some embodiments of the present disclosure. Similar to the embodiments illustrated by FIG. 1A, the embodiments illustrated by FIG. 3A are also regarded as a basic configuration compared with modified embodiments which will be shown later in FIGS. 3B and 3C. The main difference between the embodiments illustrated by FIG. 3A and embodiments illustrated by FIG. 1A is that, the geometrical centers C1 respectively of three sub-pixels 3122 are arranged in a stripe shape within one pixel 312. Similar structural features between FIGS. 3A and 1A will not be repeated herein. The embodiments illustrated by FIG. 3A also has the geometrical centers C1 of the sub-pixels 3122 that are overlapped in a direction normal to an extension direction of the substrate 310 with the geometrical centers C2 of the light emitting devices 320 respectively in one of the pixels 312. A distance between one of the geometrical centers C1 of the sub-pixels 3122 and the common geometrical center C5 of the light emitting devices 320 located within one pixel 312 is the distance D7, a distance between the geometrical center C2 of the light emitting device 320 within said sub-pixel 3122 and the common geometrical center C5 is the distance D8, and the distance D7 is equal to the distance D8 in the embodiments as illustrated by FIG. 3A.

Reference is made to FIGS. 3A and 3B. FIG. 3B is a schematic top view of a portion of a display 300b with some pixels 312 having sub-pixels 3122 defined thereon and some light emitting devices 320 respectively located within the sub-pixels 3122 according to some embodiments of the present disclosure. The main difference between the embodiments illustrated by FIG. 3B and the embodiments illustrated by FIG. 3A is that, one of the light emitting devices 320 in the indicated pixel 312 is dislocated by a distance towards the common geometrical center C5 shown in FIG. 3A (i.e., the original common geometrical center C5 which is without dislocation). After the dislocation, a distance D8′ is the distance between the geometrical center C2 of said one of the light emitting devices 320 with said dislocation and a dislocated common geometrical center C5′ as shown in FIG. 3B. Therefore, a distance D7′ (which also becomes greater in length as compared with the distance D7 shown in FIG. 3A) is greater than the distance D8′ for one of the sub-pixels 3122 in the pixel 312 of the embodiments as illustrated by FIG. 3B, and thus under a condition within the same pixel 312, a relative position of one of the light emitting devices 320 with respect to its corresponding sub-pixel 3122 is different from relative positions of a remaining two light emitting devices 320 with respect to their respectively corresponding sub-pixels 3122. As such, the pixel 312 as shown in FIG. 3B can have a better light mixing effect of the light emitting devices 320 within said pixel 312 due to a more concentrated arrangement compared with that of FIG. 3A. It should be noted that, although FIG. 3B only demonstrates a dislocation of one light emitting device 312 in one indicated pixel 312, other light emitting devices 320 in pixels other than the indicated pixel 312 (which are also pixels 312 but without indication for clarity and simplicity of the figure) can also have dislocations and shall not be limited by FIG. 3B.

Reference is made to FIG. 3C. FIG. 3C is a schematic top view of a portion of a display 300c with some pixels 312 having sub-pixels 3122 defined thereon and some light emitting devices 320 respectively located within the sub-pixels 3122 according to some embodiments of the present disclosure. The main difference between the embodiments illustrated by FIG. 3C and the embodiments illustrated by FIG. 3A is that, all of the light emitting devices 320 except the middle one (i.e., the one in which the geometrical center C2 of the middle light emitting device 320 is overlapped with the common geometrical center C5 of the light emitting devices 320 in a direction normal to an extension direction of the substrate 310) within the same pixel 312 are dislocated by a distance (D7-D9) towards the common geometrical center C5 as compared with the embodiments as illustrated by FIG. 3A. The distance D9 is the distance between the geometrical center C2 of the light emitting device 320 (except said middle one) in one of the sub-pixels 3122 and the common geometrical center C5 as shown in FIG. 3C. Therefore, the distance D7 is greater than the distance D9 for the sub-pixels 3122 in the pixel 312 of the embodiments as illustrated by FIG. 3C, and under a condition within the same pixel 312, relative positions of the light emitting devices 320 with respect to their corresponding sub-pixels 3122 respectively are different from one another. As such, the pixel 312 as shown in FIG. 3C can have a better light mixing effect of the light emitting devices 320 within said pixel 312 due to a more concentrated arrangement compared with that of FIG. 3A. It should be noted that, although FIG. 3C only demonstrates the same distance of dislocations of all light emitting devices 320 except said middle one, different distances of dislocations can be adopted for different light emitting devices 320 according to practical applications and shall not be limited by FIG. 3C.

The following shows some modified embodiments. Since these embodiments can be regarded as modifications based on the embodiments illustrated by FIGS. 1A to 1C, 2A to 2C, and 3A to 3C as mentioned above, similar or repeated content will be omitted herein to simplify the content of the description.

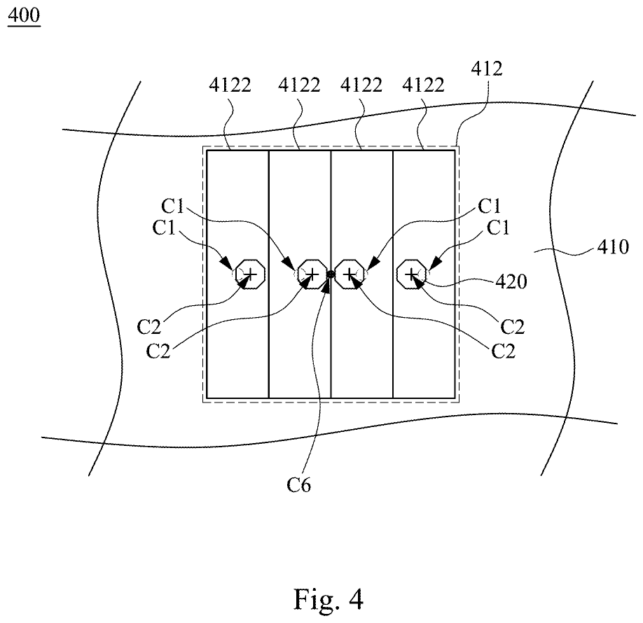

Reference is made to FIG. 4. FIG. 4 is a schematic top view of a portion of a display 400 with a pixel 412 having sub-pixels 4122 defined thereon and some light emitting devices 420 respectively located within the sub-pixels 4122 according to some embodiments of the present disclosure. In some embodiments, geometrical centers respectively of four sub-pixels are arranged in a stripe arrangement. The main difference between the embodiments illustrated by FIG. 4 and the embodiments illustrated by FIG. 3C is that, there are geometrical centers C1 respectively of four sub-pixels 4122 instead of three arranged in a stripe arrangement within one pixel 412. Four light emitting devices 420 respectively located within the sub-pixels 4122 are dislocated towards their common geometrical center C6 compared with a case that the geometrical centers C2 of the light emitting devices 420 are overlapped with the geometrical centers C1 of the sub-pixels 4122 respectively in a direction normal to an extension direction of the substrate 410, and thus under a condition within the pixel 412, a relative position of one of the light emitting devices 420 with respect to its corresponding sub-pixel 4122 is different from at least one of relative positions of a remaining three of the light emitting devices 420 with respect to their respectively corresponding sub-pixels 4122. As such, the pixel 412 as shown in FIG. 4 can have a better light mixing effect of the light emitting devices 420 within said pixel 412 due to a more concentrated arrangement compared with the configuration that the geometrical centers C2 of the light emitting devices 420 are overlapped with the geometrical centers C1 of the sub-pixels 4122 respectively in a direction normal to an extension direction of the substrate 410.

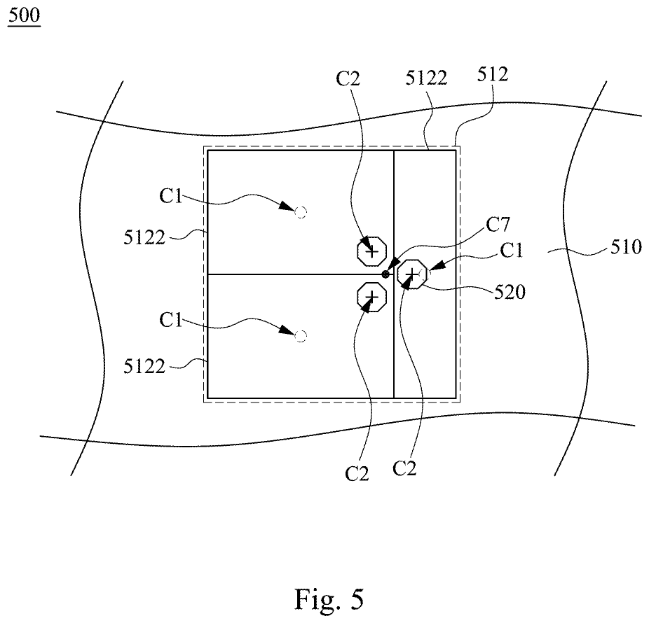

The embodiments illustrated by the above figures only show that a shape of each of the sub-pixels and an area of each of the sub-pixels are the same. In some other embodiments, a shape of one of the sub-pixels is different from a shape of a remaining part of the sub-pixels in the same pixel. In some other embodiments, an area of one of the sub-pixels is different from an area of a remaining part of the sub-pixels in the same pixel. Reference is made to FIG. 5. FIG. 5 is a schematic top view of a portion of a display 500 with a pixel 512 having sub-pixels 5122 with different shapes defined thereon and some light emitting devices 520 respectively located within the sub-pixels 5122 according to some embodiments of the present disclosure. The main difference between the embodiments illustrated by FIG. 5 and the embodiments illustrated by FIG. 1C is that, at least one of the sub-pixels 5122 is different in shape and/or area from other sub-pixels 5122 within the same pixel 512. That is, configurations of the present disclosure are not restricted to the same shape of sub-pixels within one pixel.

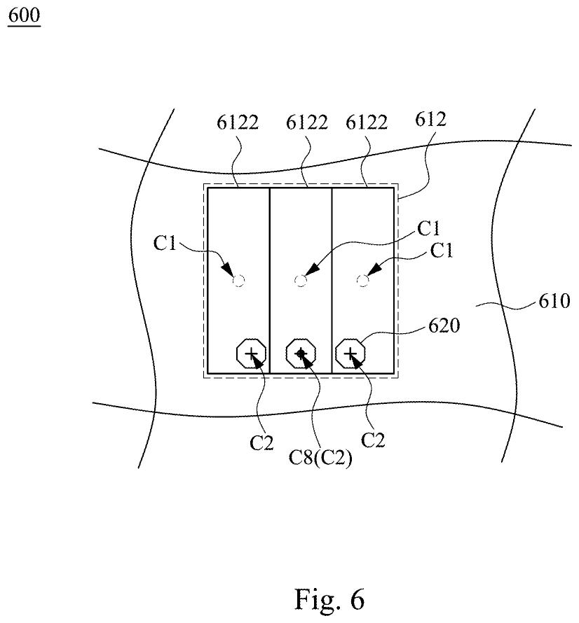

Reference is made to FIG. 6. FIG. 6 is a schematic top view of a portion of a display 600 with a pixel 612 having sub-pixels 6122 defined thereon and some light emitting devices 620 respectively located within the sub-pixels 6122 according to some embodiments of the present disclosure. The main difference between the embodiments illustrated by FIG. 6 and the embodiments illustrated by FIG. 3C is that, besides the dislocations as illustrated by FIG. 3C, three micro devices 620 further have a common dislocation which is downward compared with the position of the three micro devices 320 in the pixel 312 as shown in FIG. 3C. The embodiments illustrated by FIG. 6 show that, locations of the light emitting devices 620 relative to their corresponding sub-pixels 6122 respectively are flexible and are not restricted to embodiments as shown in FIGS. 1A to 5.

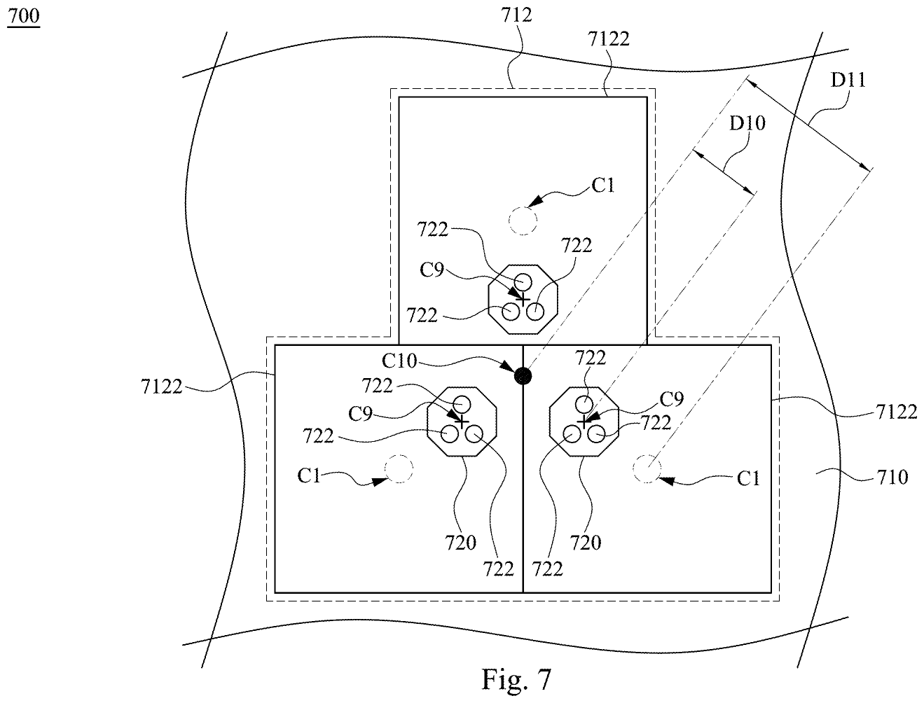

Reference is made to FIG. 7. FIG. 7 is a schematic top view of a portion of a display 700 with a pixel 712 having sub-pixels 7122 defined thereon and some light emitting devices 720 respectively located within the sub-pixels 7122 according to some embodiments of the present disclosure. In some embodiments, each of the light emitting devices 720 has at least one light emitting areas 722. In some embodiments, one of said light emitting devices 720 has a plurality of light emitting areas 722. For example, in FIG. 7, each of three light emitting devices 720 has three light emitting areas 722. Geometrical centers C9 of the three light emitting areas 722 of each of the light emitting devices 720 respectively are indicated in FIG. 7. The light emitting areas 722 of one light emitting device 720 have their own geometrical center C9, and a common geometrical center C10 of nine light emitting areas 722 within the same pixel 712 is also indicated. In the configuration as shown in FIG. 7, the definition of a distance between the geometrical center of the light emitting devices 720 in one of the sub-pixels 7122 and the common geometrical center of the light emitting devices 720 within the same pixel 712 becomes a definition of a distance D10 between a geometrical center C9 of the light emitting areas 722 of one of the light emitting devices 720 and the common geometrical center C10 of the light emitting areas 722 within the same pixel 712. That is, the distance D11 between the geometrical center C1 of one of said sub-pixels 7122 and the common geometrical center C10 of the light emitting areas 722 within the same pixel 712 is greater than the distance D10. As such, the pixel 712 as shown in FIG. 7 can have a better light mixing effect of the light emitting devices 720 within said pixel 712 due to a more concentrated arrangement compared with that of FIGS. 1A, 2A and 3A. It should be noted that, although FIG. 7 only demonstrates three light emitting areas 722 in one light emitting device 720, the number of light emitting areas 722 in one light emitting device 720 should not be limited thereto, and there can be more then or less than three light emitting areas 722 in one light emitting device 720. Shapes, areas, and locations of light emitting areas 722 can also be different for different light emitting areas 722 and for different light emitting devices 720.

So far the embodiments illustrated by FIGS. 1A to 7 show only one light emitting device within one sub-pixel. However, the displays as shown above can also include more than one light emitting device located within one of the sub-pixels in certain applications. That is, embodiments with a plurality of light emitting devices within one sub-pixel also do not depart from the scope of the present disclosure. In a configuration with the plurality of light emitting devices within one sub-pixel, the definition of the common geometrical center C10 as shown in FIG. 7 is still a geometrical center of the light emitting areas within the same pixel, and the geometrical center C9 as shown in FIG. 7 is modified to be a geometrical center of light emitting areas within the same sub-pixel and not restricted to the same light emitting device. Other structural restrictions similar or repeated as those of embodiments shown in FIGS. 1A to 7 will not be repeated herein.

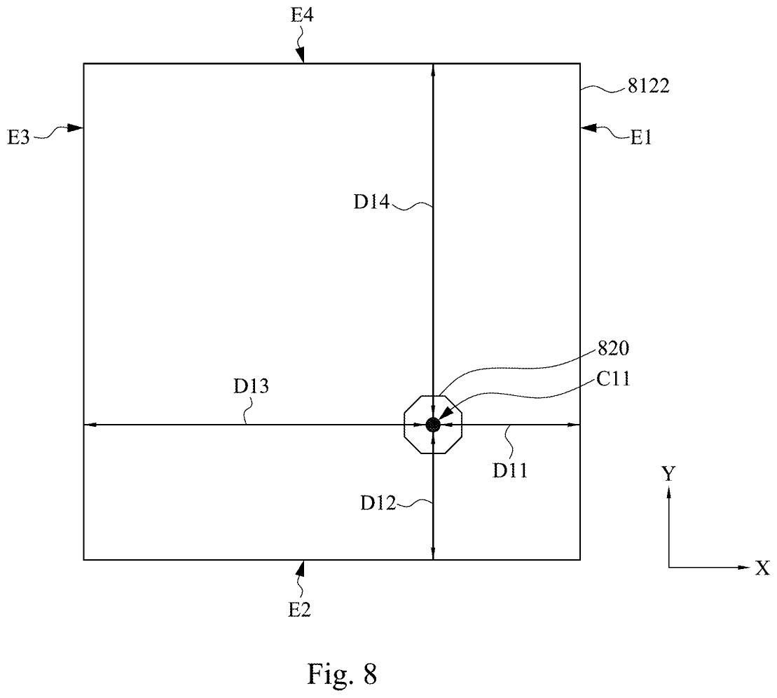

Reference is made to FIG. 8. FIG. 8 is a schematic top view of a sub-pixel 8122 with a light emitting device 820 located therein according to some embodiments of the present disclosure. A direction x and a direction y are respectively indicated in directions parallel to two orthogonal edges of the sub-pixel 8122 respectively for convenience in illustration since the sub-pixel 8122 exemplified in FIG. 8 is square in shape. The embodiments of the sub-pixel 8122 and the light emitting device 820 illustrated by FIG. 8 can be incorporated into some of the previous embodiments such as embodiments illustrated by FIGS. 1B, 1C, 2B, 2C, 5, 6 and 7, but should not be restricted thereto. In some embodiments, a position of the geometrical center C11 of the light emitting device 820 in a sub-pixel 8122 relative to the sub-pixel 8122 with respect to any two opposite edges of the sub-pixel 8122 is asymmetric. Said two opposite edges, such as edges E1 and E3, or edges E2 and E4 respectively, are spaced apart from each other. Specifically, one embodiment of said asymmetric relation is that, a distance D11 is different from a distance D13, and a distance D12 is different from a distance D14, respectively. The distance D11 is a shortest distance between the geometrical center C11 and the edge E1, the distance D12 is a shortest distance between the geometrical center C11 and the edge E2, the distance D13 is a shortest distance between the geometrical center C11 and the edge E3, and the distance D14 is a shortest distance between the geometrical center C11 and the edge E4. In other words, an upper part and a lower part of the sub-pixel 8122 relative to an axis which is parallel to the direction x and passing through the geometrical center C11 is not symmetric, and a left part and a right part of the sub-pixel 8122 relative to an axis which is parallel to the direction y and passing through the geometrical center C11 is not symmetric.

In the above embodiments as illustrated by FIGS. 1A to 8, the light emitting devices 120, 220, 320, 420, 520, 620, 720, 820 can emit different colors, such as light emitting diodes with different colors. For example, in FIGS. 1A to 1C, 3A to 3C, and 5 to 7, the exemplified three light emitting devices 120, 320, 520, 720 may emit lights with wavelength corresponding to red, green, and blue respectively, but should not be limited thereto. In FIGS. 2A to 2C, and 4, the exemplified four light emitting devices 220, 420 may emit lights with wavelength corresponding to red, green, blue, and yellow respectively, but should not be limited thereto. Besides, light emitting devices with wavelength corresponding to cyan and ultraviolet may also be chosen as one of the light emitting devices adopted by the embodiments as illustrated by FIGS. 1A to 7. In still some other embodiments, more than four sub-pixels can be defined in one pixel. For example, there can be five sub-pixels defined in one pixel, and each of the sub-pixels has a light emitting device located therein. The wavelength emitted by each of the light emitting devices can be chosen from the colors mentioned above, but should not be limited thereto. The five geometrical centers of the sub-pixels can be arranged in trapezoidal arrangement or stripe arrangement, but should not be limited thereto.

In summary, a display with dislocated light emitting device with respect to geometrical centers of each of the sub-pixels respectively is provided. Said dislocations realize a structural relation that a distance between a geometrical center of one sub-pixel in one pixel and a common geometrical center of light emitting devices in the pixel is greater than a distance between a geometrical center of the light emitting device in the sub-pixel and the common geometrical center of the light emitting devices in the pixel. As such, the pixel can have a better light mixing effect of the light emitting devices therein due to concentrated arrangement.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. A display, comprising:
a substrate having at least one pixel defined thereon, a plurality of sub-pixels being defined in said pixel, and each of the sub-pixels having a geometrical center; and
a plurality of light emitting devices respectively located within said sub-pixels, wherein a distance between the geometrical center of one of said sub-pixels and a common geometrical center of said light emitting devices is greater than a distance between a geometrical center of the light emitting device in said one of said sub-pixels and the common geometrical center of said light emitting devices, and a relative position of the light emitting device in said one of said sub-pixels is different from at least one of relative positions of a remaining part of said light emitting devices;
wherein the relative position of the light emitting device in each of the sub-pixels is in respect to the geometrical center of said each of the sub-pixels.

2. The display of claim 1, wherein each of said light emitting devices has at least one light emitting area.

3. The display of claim 2, wherein one of said light emitting devices has a plurality of light emitting areas, and a distance between said geometrical center of one of said sub-pixels in which said one of said light emitting devices located within and a common geometrical center of the light emitting areas of the light emitting devices in said pixel is greater than a distance between a geometrical center of the light emitting areas of said one of said light emitting devices in said one of said sub-pixels and the common geometrical center of the light emitting areas of the light emitting devices in said pixel.

4. The display of claim 1, wherein geometrical centers respectively of three of said sub-pixels are arranged in a triangular arrangement.

5. The display of claim 1, wherein geometrical centers respectively of three of said sub-pixels are arranged in a stripe arrangement.

6. The display of claim 1, wherein geometrical centers respectively of four of said sub-pixels are arranged in a quadrilateral arrangement.

7. The display of claim 1, wherein geometrical centers respectively of four of said sub-pixels are arranged in a stripe arrangement.

8. The display of claim 1, wherein a shape of each of said sub-pixels are the same.

9. The display of claim 1, wherein a shape of one of said sub-pixels is different from a shape of a remaining part of said sub-pixels.

10. The display of claim 1, wherein an area of each of said sub-pixels are the same.

11. The display of claim 1, wherein an area of one of said sub-pixels is different from an area of a remaining part of said sub-pixels.

12. The display of claim 1, further comprising at least one more light emitting device located within one of said sub-pixels.

13. The display of claim 1, wherein a position of the geometrical center of the light emitting device in said one of said sub-pixels relative to said one of said sub-pixels with respect to any two opposite edges of said one of said sub-pixels is asymmetric.
